(19) United States
(12) Patent Application Publication
(10) Pub. No.: US 2020/0174368 A1
(43) Pub. Date: Jun. 4, 2020

(54) POSITIVE-TYPE PHOTOSENSITIVE RESIN COMPOSITION AND CURED FILM PREPARED THEREFROM

(71) Applicant: ROHM AND HAAS ELECTRONIC MATERIALS KOREA LTD., Chungcheongnam-do (KR)

(72) Inventors: Yeonok KIM, Gyeonggi-do (KR); Geun HUH, Gyeonggi-do (KR); Ju-Young JUNG, Gyeonggi-do (KR); Jong Han YANG, Gyeonggi-do (KR)

(21) Appl. No.: 16/664,989

(22) Filed: Oct. 28, 2019

(30) Foreign Application Priority Data
Nov. 29, 2018 (KR) 10-2018-0150669

(51) Int. Cl. G03F 7/039; G03F 7/075; G03F 7/023; C08F 220/14

(52) U.S. Cl. CPC G03F 7/039; C08F 220/14; G03F 7/0233; G03F 7/0757

(57) ABSTRACT

The present invention relates to a photosensitive resin composition and a cured film prepared therefrom. The positive-type photosensitive resin composition comprises an acrylic copolymer, which has a functional group that can freely rotate in the polymer, whereby the composition is capable of further enhancing the sensitivity.

### TECHNICAL FIELD

The present invention relates to a photosensitive resin composition and a cured film prepared therefrom. More specifically, the present invention relates to a positive-type photosensitive resin composition, which provides excellent sensitivity, and a cured film prepared therefrom to be used in a liquid crystal display, an organic EL display, and the like.

### BACKGROUND ART

In a display device such as a thin film transistor (TFT) type liquid crystal display device, an inorganic protective film made of, for example, silicon nitride has been used as a protective film for protecting and insulating the TFT circuit. However, since such an inorganic protective film has a problem that it is difficult to enhance the aperture ratio due to its high dielectric constant, the demand for an organic insulating film having a low dielectric constant is increasing in order to address this problem.

A photosensitive resin, which is a polymeric compound that is chemically reacted with light and an electron beam to change its solubility to a specific solvent, is generally used. The photosensitive resin is classified into a positive type and a negative type depending on the solubility of the exposed portion during development. In the positive type, an exposed portion is dissolved by a developer to form a pattern. In the negative type, an exposed portion is not dissolved by a developer, and the unexposed portion is dissolved to form a pattern.

Since a positive-type organic insulating film has no photo-curing factor as compared with a negative-type organic insulating film, it has the disadvantage that it is difficult to secure sensitivity and adhesion to an underlying film.

Thus, a photosensitive resin composition and a cured film prepared therefrom have been proposed in which a polysiloxane resin and an acrylic resin are employed together, thereby having excellent sensitivity and adhesiveness (see Japanese Patent No. 5,099,140). However, the sensitivity has not yet been improved to a satisfactory level.

### DISCLOSURE OF INVENTION

### Technical Problem

Accordingly, in order to solve the above-mentioned problems, the present invention aims to provide a positive-type photosensitive resin composition that comprises a polysiloxane resin and an acrylic resin, wherein the sensitivity can be further enhanced by introducing a functional group that can freely rotate in a polymer into the acrylic copolymer; and a cured film prepared therefrom to be used in a liquid crystal display, an organic EL display, and the like.

### Solution to Problem

In order to accomplish the above object, the present invention provides a positive-type photosensitive resin composition, which comprises (A) an acrylic copolymer; (B) a siloxane copolymer; and (C) a 1,2-quinonediazide compound, wherein the acrylic copolymer (A) comprises a structural unit (a-1) represented by the following Formula 1:

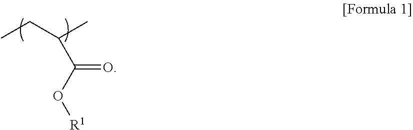

In the above Formula 1, R¹ is C₁₋₄ alkyl.

In order to accomplish another object, the present invention provides a cured film prepared from the positive-type photosensitive resin composition.

### Advantageous Effects of Invention

The positive-type photosensitive resin composition according to the present invention comprises an acrylic copolymer, which has a functional group that can freely rotate in the polymer, whereby the composition is readily dissolved to a developer during the development step, thereby enhancing the sensitivity.

### BEST MODE FOR CARRYING OUT THE INVENTION

The positive-type photosensitive resin composition of the present invention comprises (A) an acrylic copolymer; (B) a siloxane copolymer; and (C) a 1,2-quinonediazide compound, wherein the acrylic copolymer (A) comprises a structural unit (a-1) represented by the following Formula 1:

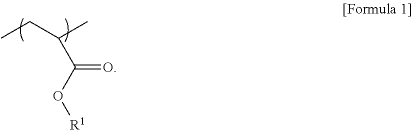

In the above Formula 1, R¹ is C₁₋₄ alkyl.

As used herein, the term “(meth)acryl” refers to “acryl” and/or “methacryl,” and the term “(meth)acrylate” refers to “acrylate” and/or “methacrylate.”

The weight average molecular weight (g/mole, Da) of each component as described below is measured by gel permeation chromatography (GPC, eluent: tetrahydrofuran) referenced to a polystyrene standard.

(A) Acrylic Copolymer

The positive-type photosensitive resin composition according to the present invention may comprise an acrylic copolymer (A).

The acrylic copolymer (A) may comprise a structural unit (a-1) represented by the following Formula 1:

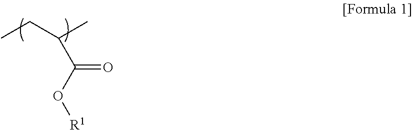

In the above Formula 1, R¹ is C₁₋₄ alkyl.

Specifically, the functional group in the structural unit (a-1) can freely rotate in the polymer, which allows the penetration of a developer during the development. Thus, a coating film is more readily developed during the development after the exposure to light, thereby securing excellent sensitivity.

The content of the structural unit (a-1) may be 1 to 30% by weight, preferably 2 to 20% by weight, based on the total weight of the acrylic copolymer (A). Within the above range, it is possible to attain a pattern of a coating film with excellent sensitivity. The acrylic copolymer (A) may further comprise a structural unit (a-2) represented by the following Formula 1-1:

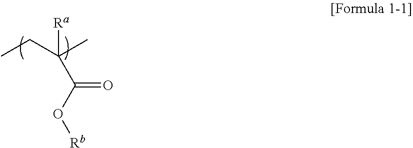

In the above Formula 1-1, R^{a} and R^{b} are each independently C₁₋₄ alkyl.

As the acrylic copolymer (A) comprises the structural unit (a-1) and the structural unit (a-2) at the same time, it is advantageous to improving the sensitivity while maintaining the film retention rate.

The structural unit (a-1) and the structural unit (a-2) may have a content ratio of 1:99 to 80:20, preferably a content ratio of 5:95 to 40:60. Within the above range, it is advantageous to improving the sensitivity while maintaining the film retention rate.

The acrylic copolymer (A) is an alkali-soluble resin for materializing developability in the development step and also plays the role of a base for forming a film upon coating and a structure for forming a final pattern.

The acrylic copolymer (A) may further comprise a structural unit (a-3) derived from an ethylenically unsaturated carboxylic acid, an ethylenically unsaturated carboxylic anhydride, or a combination thereof.

Specifically, the structural unit (a-3) may be derived from an ethylenically unsaturated carboxylic acid, an ethylenically unsaturated carboxylic anhydride, or a combination thereof. The ethylenically unsaturated carboxylic acid, the ethylenically unsaturated carboxylic anhydride, or a combination thereof is a polymerizable unsaturated compound containing at least one carboxyl group in the molecule. It may be at least one selected from an unsaturated monocarboxylic acid such as (meth)acrylic acid, crotonic acid, α-chloroacrylic acid, and cinnamic acid; an unsaturated dicarboxylic acid and an anhydride thereof such as maleic acid, maleic anhydride, fumaric acid, itaconic acid, itaconic anhydride, citraconic acid, citraconic anhydride, and mesaconic acid; an unsaturated polycarboxylic acid having three or more valences and an anhydride thereof; and a mono[(meth)acryloyloxyalkyl] ester of a polycarboxylic acid of divalence or more such as mono[2-(meth)acryloyloxyethyl] succinate, mono[2-(meth)acryloyloxyethyl] phthalate, and the like. But it is not limited thereto. (Meth)acrylic acid among the above is preferable from the viewpoint of developability.

The content of the structural unit (a-3) may be 5 to 30% by weight based on the total weight of the acrylic copolymer (A). Within the above range, it is possible to attain a pattern of a coating film with good developability.

The acrylic copolymer (A) may further comprise a structural unit (a-4) derived from an ethylenically unsaturated compound different from the structural units (a-1), (a-2), and (a-3). The ethylenically unsaturated compound different from the structural units (a-1), (b-2), and (a-3) may be at least one selected from the group consisting of an ethylenically unsaturated compound having an aromatic ring such as phenyl (meth)acrylate, benzyl (meth)acrylate, 2-phenoxyethyl (meth)acrylate, phenoxy diethylene glycol (meth)acrylate, p-nonylphenoxy polyethylene glycol (meth)acrylate, p-nonylphenoxy polypropylene glycol (meth)acrylate, tribromophenyl (meth)acrylate, styrene, methylstyrene, dimethylstyrene, trimethylstyrene, ethylstyrene, diethylstyrene, triethylstyrene, propylstyrene, butylstyrene, hexylstyrene, heptylstyrene, octylstyrene, fluorostyrene, chlorostyrene, bromostyrene, iodostyrene, methoxystyrene, ethoxystyrene, propoxystyrene, p-hydroxy-α-methylstyrene, acetylstyrene, vinyl toluene, divinylbenzene, vinylphenol, o-vinylbenzyl methyl ether, m-vinylbenzyl methyl ether, and p-vinylbenzyl methyl ether; an unsaturated carboxylic acid ester such as dimethylaminoethyl (meth)acrylate, cyclohexyl (meth)acrylate, ethylhexyl (meth)acrylate, tetrahydrofurfuryl (meth)acrylate, hydroxyethyl (meth)acrylate, 2-hydroxypropyl (meth)acrylate, 2-hydroxy-3-chloropropyl (meth)acrylate, 4-hydroxybutyl (meth)acrylate, glycerol (meth)acrylate, methyl α-hydroxymethylacrylate, ethyl α-hydroxymethylacrylate, propyl α-hydroxymethylacrylate, butyl α-hydroxymethylacrylate, 2-methoxyethyl (meth)acrylate, 3-methoxybutyl (meth)acrylate, ethoxy diethylene glycol (meth)acrylate, methoxy triethylene glycol (meth)acrylate, methoxy tripropylene glycol (meth)acrylate, poly(ethylene glycol) methyl ether (meth)acrylate, tetrafluoropropyl (meth)acrylate, 1,1,1,3,3,3-hexafluoroisopropyl (meth)acrylate, octafluoropentyl (meth)acrylate, heptadecafluorodecyl (meth)acrylate, isobornyl (meth)acrylate, dicyclopentanyl (meth)acrylate, and dicyclopentenyl (meth)acrylate; an unsaturated monomer containing an epoxy group such as glycidyl (meth)acrylate, 3,4-epoxybutyl (meth)acrylate, 4,5-epoxypentyl (meth)acrylate, 5,6-epoxyhexyl (meth)acrylate, 6,7-epoxyheptyl (meth)acrylate, 2,3-epoxycyclopentyl (meth)acrylate, 3,4-epoxycyclohexyl (meth)acrylate, α-ethyl glycidyl acrylate, α-n-propyl glycidyl acrylate, α-n-butyl glycidyl acrylate, N-(4-(2,3-epoxypropoxy)-3,5-dimethylbenzyl)acrylamide, N-(4-(2,3-epoxypropoxy)-3,5-dimethylphenylpropyl)acrylamide, 4-hydroxybutyl (meth)acrylate glycidyl ether, allyl glycidyl ether, and 2-methylallyl glycidyl ether; an N-vinyl tertiary amine containing an N-vinyl group such as N-vinyl pyrrolidone, N-vinyl carbazole, and N-vinyl morpholine; an unsaturated ether such as vinyl methyl ether and vinyl ethyl ether; and an unsaturated imide such as N-phenylmaleimide, N-(4-chlorophenyl)maleimide, N-(4-hydroxyphenyl)maleimide, and N-cyclohexylmaleimide.

The structural unit derived from the above-exemplified compounds may be comprised in the copolymer alone or in combination of two or more.

If the copolymer preferably comprises a structural unit derived from an ethylenically unsaturated compound containing an epoxy group among the above, more preferably a structural unit derived from glycidyl (meth)acrylate or 3,4-epoxycyclohexyl (meth)acrylate, it may be more advantageous in terms of the copolymerizability and improvement in the strength of an insulating film.

The content of the structural unit (a-4) may be 5 to 70% by weight, preferably 15 to 65% by weight, based on the total weight of the structural units constituting the acrylic copolymer (A). Within the above range, it is possible to increase the mechanical properties and the thermosetting factors of the acrylic copolymer (i.e., alkali-soluble resin), so that the mechanical film properties and the chemical resistance characteristics upon the formation of a coating film of the photosensitive resin composition can be remarkably enhanced.

The acrylic copolymer (A) may be prepared by compounding each of the compounds that provide the structural units (a-1), (a-2), (a-3), and (a-4), and adding thereto a molecular weight controlling agent, a polymerization initiator, a solvent, and the like, followed by charging nitrogen thereto and slowly stirring the mixture for polymerization. The molecular weight controlling agent may be a mercaptan compound such as butyl mercaptan, octyl mercaptan, lauryl mercaptan, or the like, or an α-methylstyrene dimer, but it is not particularly limited thereto.

The polymerization initiator may be an azo compound such as 2,2′-azobisisobutyronitrile, 2,2′-azobis(2,4-dimethylvaleronitrile), and 2,2′-azobis(4-methoxy-2,4-dimethylvaleronitrile); or benzoyl peroxide; lauryl peroxide; t-butyl peroxypivalate; 1,1-bis(t-butylperoxy)cyclohexane, or the like, but it is not limited thereto. The polymerization initiator may be used alone or in combination of two or more thereof.

In addition, the solvent may be any solvent commonly used in the preparation of an acrylic copolymer (A). It may preferably be methyl 3-methoxypropionate or propylene glycol monomethyl ether acetate (PGMEA).

In particular, it is possible to reduce the residual amount of unreacted monomers by keeping the reaction time longer while maintaining the reaction conditions to be milder during the polymerization reaction.

The reaction conditions and the reaction time are not particularly limited. For example, the reaction temperature may be adjusted to a temperature lower than the conventional temperature, for example, from room temperature to 60□ or from room temperature to 65□. Then, the reaction time is to be maintained until a sufficient reaction takes place.

It is possible to reduce the residual amount of unreacted monomers in the acrylic copolymer (A) to a very minute level when the acrylic copolymer (A) is prepared by the above process.

Here, the term unreacted monomers (or residual monomers) of the acrylic copolymer (A) as used herein refers to the amount of the compounds (i.e., monomers) that aim to provide the structural units (a-1) to (a-4) of the acrylic copolymer (A), but do not participate in the reaction (i.e., do not form a chain of the copolymer).

Specifically, the amount of unreacted monomers of the acrylic copolymer (A) remaining in the photosensitive resin composition of the present invention may be 2 parts by weight or less, preferably 1 part by weight or less, based on 100 parts by weight of the copolymer (on the basis of solids content).

Here, the term solids content refers to the amount of the composition, exclusive of solvents.

The weight average molecular weight (Mw) of the acrylic copolymer (A) thus prepared may be in the range of 5,000 to 20,000 Da, preferably 8,000 to 13,000 Da. Within the above range, the adhesiveness to a substrate is excellent, the physical and chemical properties are good, and the viscosity is proper.

The acrylic copolymer (A) may be employed in an amount of 10 to 90% by weight, preferably 30 to 80% by weight, more preferably 45 to 65% by weight, based on the total weight of the photosensitive resin composition on the basis of the solids content, exclusive of solvents. Within the above range, the developability is appropriately controlled, which is advantageous in terms of film retention.

(B) Siloxane Copolymer

The positive-type photosensitive resin composition according to the present invention may comprise a siloxane copolymer (or polysiloxane).

The siloxane copolymer (B) includes a condensate of a silane compound and/or a hydrolysate thereof. In such event, the silane compound or the hydrolysate thereof may be a monofunctional to tetrafunctional silane compound.

As a result, the siloxane copolymer (B) may comprise a siloxane structural unit selected from the following Q, T, D, and M types:
Q type siloxane structural unit: a siloxane structural unit comprising a silicon atom and four adjacent oxygen atoms, which may be derived from, e.g., a tetrafunctional silane compound or a hydrolysate of a silane compound that has four hydrolyzable groups.
T type siloxane structural unit: a siloxane structural unit comprising a silicon atom and three adjacent oxygen atoms, which may be derived from, e.g., a trifunctional silane compound or a hydrolysate of a silane compound that has three hydrolyzable groups.
D type siloxane structural unit: a siloxane structural unit comprising a silicon atom and two adjacent oxygen atoms (i.e., a linear siloxane structural unit), which may be derived from, e.g., a difunctional silane compound or a hydrolysate of a silane compound that has two hydrolyzable groups.
M type siloxane structural unit: a siloxane structural unit comprising a silicon atom and one adjacent oxygen atom, which may be derived from, e.g., a monofunctional silane compound or a hydrolysate of a silane compound that has one hydrolyzable group.

For example, the siloxane copolymer (B) may comprise a structural unit derived from a silane compound represented by the following Formula 2, and the siloxane polymer (B) may be, for example, a condensate of a silane compound represented by the following Formula 2 and/or a hydrolysate thereof.

(R³)ₙSi(OR⁴)₄₋ₙ [Formula 2]

In the above Formula 2, n is an integer of 0 to 3, R³ is each independently C₁₋₁₂ alkyl, C₂₋₁₀ alkenyl, C₆₋₁₅ aryl, 3- to 12-membered heteroalkyl, 4- to 10-membered heteroalkenyl, or 6- to 15-membered heteroaryl, and R⁴ is each independently hydrogen, C₁₋₆ alkyl, C₂₋₆ acyl, or C₆₋₁₅ aryl, wherein the heteroalkyl, the heteroalkenyl, and the heteroaryl groups each independently have at least one heteroatom selected from the group consisting of O, N, and S.

Examples of the structural unit wherein R³ has a heteroatom include an ether, an ester, and a sulfide.

The compound may be a tetrafunctional silane compound where n is 0, a trifunctional silane compound where n is 1, a difunctional silane compound where n is 2, or a monofunctional silane compound where n is 3.

Particular examples of the silane compound may include, e.g., as the tetrafunctional silane compound, tetraacetoxysilane, tetramethoxysilane, tetraethoxysilane, tetrabutoxysilane, tetraphenoxysilane, tetrabenzyloxysilane, and tetrapropoxysilane; as the trifunctional silane compound, methyltrichlorosilane, methyltrimethoxysilane, methyltriethoxysilane, methyltriisopropoxysilane, methyltributoxysilane, ethyltrimethoxysilane, ethyltriethoxysilane, ethyltriisopropoxysilane, ethyltributoxysilane, butyltrimethoxysilane, pentafluorophenyltrimethoxysilane, phenyltrimethoxysilane, phenyltriethoxysilane, d³-methyltrimethoxysilane, nonafluorobutylethyltrimethoxysilane, trifluoromethyltrimethoxysilane, n-propyltrimethoxysilane, n-propyltriethoxysilane, n-butyltriethoxysilane, n-hexyltrimethoxysilane, n-hexyltriethoxysilane, decyltrimethoxysilane, vinyltrimethoxysilane, vinyltriethoxysilane, 3-methacryloxypropyltrimethoxysilane, 3-methacryloxypropyltriethoxysilane, 3-acryloxypropyltrimethoxysilane, 3-acryloxypropyltriethoxysilane, p-hydroxyphenyltrimethoxysilane, 1-(p-hydroxyphenyl)ethyltrimethoxysilane, 2-(p-hydroxyphenyl)ethyltrimethoxysilane, 4-hydroxy-5-(p-hydroxyphenylcarbonyloxy)pentyltrimethoxysilane, trifluoromethyltriethoxysilane, 3,3,3-trifluoropropyltrimethoxysilane, 3-aminopropyltrimethoxysilane, 3-aminopropyltriethoxysilane, 3-glycidoxypropyltrimethoxysilane, 3-glycidoxypropyltriethoxysilane, 2-(3,4-epoxycyclohexyl)ethyltrimethoxysilane, 2-(3,4-epoxycyclohexyl)ethyltriethoxysilane, [(3-ethyl-3-oxetanyl)methoxy]propyltrimethoxysilane, [(3-ethyl-3-oxetanyl)methoxy]propyltriethoxysilane, 3-mercaptopropyltrimethoxysilane, and 3-trimethoxysilylpropylsuccinic acid; as the difunctional silane compound, dimethyldiacetoxysilane, dimethyldimethoxysilane, diphenyldimethoxysilane, diphenyldiethoxysilane, diphenyldiphenoxysilane, dibutyldimethoxysilane, dimethyldiethoxysilane, (3-glycidoxypropyl)methyldimethoxysilane, (3-glycidoxypropyl)methyldiethoxysilane, 3-(2-aminoethylamino)propyldimethoxymethylsilane, 3-aminopropyldiethoxymethylsilane, 3-chloropropyldimethoxymethylsilane, 3-mercaptopropyldimethoxymethylsilane, cyclohexyldimethoxymethylsilane, diethoxymethylvinylsilane, dimethoxymethylvinylsilane, and dimethoxydi-p-tolylsilane; and as the monofunctional silane compound, trimethylsilane, tributylsilane, trimethylmethoxysilane, tributylethoxysilane, (3-glycidoxypropyl)dimethylmethoxysilane, and (3-glycidoxypropyl)dimethylethoxysilane.

Preferred among the tetrafunctional silane compounds are tetramethoxysilane, tetraethoxysilane, and tetrabutoxysilane; preferred among the trifunctional silane compounds are methyltrimethoxysilane, methyltriethoxysilane, methyltriisopropoxysilane, methyltributoxysilane, phenyltrimethoxysilane, ethyltrimethoxysilane, ethyltriethoxysilane, ethyltriisopropoxysilane, ethyltributoxysilane, and butyltrimethoxysilane; preferred among the difunctional silane compounds are dimethyldimethoxysilane, diphenyldimethoxysilane, diphenyldiethoxysilane, diphenyldiphenoxysilane, dibutyldimethoxysilane, and dimethyldiethoxysilane.

These silane compounds may be used alone or in combination of two or more thereof.

The conditions for obtaining a hydrolysate or a condensate of the silane compound of the above Formula 1 are not particularly limited. For example, the silane compound of Formula 2 is optionally diluted with a solvent such as ethanol, 2-propanol, acetone, butyl acetate, or the like, and water that is essential for the reaction and an acid (e.g., hydrochloric acid, acetic acid, nitric acid, or the like) or a base (e.g., ammonia, triethylamine, cyclohexylamine, tetramethylammonium hydroxide, or the like) as a catalyst are added thereto, followed by stirring the mixture to complete the hydrolytic polymerization reaction, whereby the desired hydrolysate or condensate thereof can be obtained.

The weight average molecular weight of the condensate (i.e., siloxane polymer) obtained by the hydrolytic polymerization of the silane compound of the above Formula 2 is preferably in a range of 500 to 50,000 Da. Within the above range, it is more preferable in terms of the film formation characteristics, solubility, dissolution rate to a developer, and the like.

The type and amount of the solvent or the acid or base catalyst are not particularly limited. In addition, the hydrolytic polymerization reaction may be carried out at a low temperature of 20□ or lower. Alternatively, the reaction may be expedited by heating or refluxing.

The required reaction time may be adjusted depending on the type and concentration of the silane structural units, reaction temperature, and the like. For example, it usually takes 15 minutes to 30 days for the reaction to proceed until the molecular weight of the condensate thus obtained becomes approximately 500 to 50,000 Da. But it is not limited thereto.

The siloxane copolymer (B) may comprise a linear siloxane structural unit (i.e., D-type siloxane structural unit). This linear siloxane structural unit may be derived from a difunctional silane compound, for example, a compound represented by the above Formula 2 where n is 2. Particularly, the siloxane copolymer (B) may comprise the structural unit derived from the silane compound of the above Formula 2 where n is 2 in an amount of 0.5 to 50% by mole, preferably 1 to 30% by mole, based on an Si atomic mole number. Within the above content range, it is possible that a cured film may have flexible characteristics while maintaining a certain level of hardness, whereby the crack resistance to an external stress can be further enhanced.

Further, the siloxane copolymer (B) may comprise a structural unit derived from a silane compound represented by the above Formula 2 where n is 1 (i.e., T-type structural unit). Preferably, the siloxane copolymer (B) may comprise the structural unit derived from the silane compound of the above Formula 2 where n is 1 in an amount ratio of 40 to 85% by mole, more preferably 50 to 80% by mole, based on an Si atomic mole number. Within the above content range, it is more advantageous to form a precise pattern profile.

In addition, in consideration of the hardness, sensitivity, and retention rate of a cured film, it is preferable that the siloxane copolymer (B) comprises the structural unit derived from a silane compound having an aryl group. For example, the siloxane copolymer (B) may comprise a structural unit derived from a silane compound having an aryl group in an amount of 30 to 70% by mole, preferably 35 to 50% by mole, based on an Si atomic mole number. Within the above content range, the compatibility of the siloxane copolymer with a 1,2-naphthoquinonediazide compound is excellent, which may prevent an excessive decrease in sensitivity while attaining more favorable transparency of a cured film. The structural unit derived from the silane compound having an aryl group may be a structural unit derived from a silane compound of the above Formula 2 where R³ is an aryl group, preferably a silane compound of the above Formula 1 where n is 1 and R³ is an aryl group, particularly a silane compound of the above Formula 2 where n is 1 and R³ is a phenyl group (i.e., siloxane structural unit of T-phenyl type).

The siloxane copolymer (B) may comprise a structural unit derived from a silane compound represented by the above Formula 2 where n is 0 (i.e., Q-type structural unit). Preferably, the siloxane copolymer (B) may comprise the structural unit derived from the silane compound represented by the above Formula 2 where n is 0 in an amount of 10 to 40% by mole, preferably 15 to 35% by mole, based on an Si atomic mole number. Within the above content range, the photosensitive resin composition may maintain its solubility to an aqueous alkaline solution at a proper level during the formation of a pattern, thereby preventing any defects caused by a reduction in the solubility or a drastic increase in the solubility of the composition.

The term “% by mole based on an Si atomic molar number” as used herein refers to a percentage of the number of moles of Si atoms contained in a specific structural unit with respect to the total number of moles of Si atoms contained in all of the structural units constituting the siloxane polymer.

The molar amount of a siloxane unit in the siloxane polymer (B) may be measured by the combination of Si-NMR, ¹H-NMR, ¹³C-NMR, IR, TOF-MS, elementary analysis, measurement of ash, and the like. For example, in order to measure the molar amount of a siloxane unit having a phenyl group, an Si-NMR analysis is performed on the entire siloxane polymer, followed by an analysis of the phenyl-bound Si peak area and the phenyl-unbound Si peak area. The molar amount can then be computed from the peak area ratio between them.

The siloxane copolymer (B) may be employed in an amount of 1 to 400 parts by weight, preferably 2 to 200 parts by weight, more preferably 5 to 80 parts by weight, based on 100 parts by weight of the acrylic copolymer (A) on the basis of the solids content excluding solvents. Within the above range, the developability is appropriately controlled, which is advantageous in terms of film retention and resolution.

(C) 1,2-Quinonediazide-Based Compound

The positive-type photosensitive resin composition according to the present invention may comprise a 1,2-quinonediazide-based compound (C).

The 1,2-quinonediazide-based compound may be a compound used as a photosensitive agent in the photoresist field.

Examples of the 1,2-quinonediazide-based compound include an ester of a phenolic compound and 1,2-benzoquinonediazide-4-sulfonic acid or 1,2-benzoquinonediazide-5-sulfonic acid; an ester of a phenolic compound and 1,2-naphthoquinonediazide-4-sulfonic acid or 1,2-naphthoquinonediazide-5-sulfonic acid; a sulfonamide of a phenolic compound in which the hydroxyl group is substituted with an amino group and 1,2-benzoquinonediazide-4-sulfonic acid or 1,2-benzoquinonediazide-5-sulfonic acid; a sulfonamide of a phenolic compound in which the hydroxyl group is substituted with an amino group and 1,2-naphthoquinonediazide-4-sulfonic acid or 1,2-naphthoquinonediazide-5-sulfonic acid. The above compounds may be used alone or in combination of two or more thereof.

Examples of the phenolic compound include 2,3,4-trihydroxybenzophenone, 2,4,6-trihydroxybenzophenone, 2,2′,4,4′-tetrahydroxybenzophenone, 2,3,3′,4-tetrahydroxybenzophenone, 2,3,4,4′-tetrahydroxybenzophenone, bis(2,4-dihydroxyphenyl)methane, bis(p-hydroxyphenyl)methane, tri(p-hydroxyphenyl)methane, 1,1,1-tri(p-hydroxyphenyl)ethane, bis(2,3,4-trihydroxyphenyl)methane, 2,2-bis(2,3,4-trihydroxyphenyl)propane, 1,1,3-tris(2,5-dimethyl-4-hydroxyphenyl)-3-phenylpropane, 4,4′-[1-[4-[1-[4-hydroxyphenyl]-1-methylethyl]phenyl]ethylidene]bisphenol, bis(2,5-dimethyl-4-hydroxyphenyl)-2-hydroxyphenylmethane, 3,3,3′,3′-tetramethyl-1,1′-spirobiindene-5,6,7,5′,6′,7′-hexanol, 2,2,4-trimethyl-7,2′,4′-trihydroxyflavane, and the like.

More particular examples of the 1,2-quinonediazide-based compound include an ester of 2,3,4-trihydroxybenzophenone and 1,2-naphthoquinonediazide-4-sulfonic acid, an ester of 2,3,4-trihydroxybenzophenone and 1,2-naphthoquinonediazide-5-sulfonic acid, an ester of 4,4′-[1-[4-[1-[4-hydroxyphenyl]-1-methylethyl]phenyl]ethylidene]bisphenol and 1,2-naphthoquinonediazide-4-sulfonic acid, an ester of 4,4′-[1-[4-[1-[4-hydroxyphenyl]-1-methylethyl]phenyl]ethylidene]bisphenol and 1,2-naphthoquinonediazide-5-sulfonic acid, and the like.

The above compounds may be used alone or in combination of two or more thereof.

If the preferable compounds exemplified above are used, the transparency of the photosensitive resin composition may be enhanced.

The 1,2-quinonediazide-based compound (C) may be employed in an amount of 2 to 30 parts by weight, preferably 5 to 25 parts by weight, based on 100 parts by weight of the acrylic copolymer (A) on the basis of the solids content. Within the above content range, a pattern is more readily formed, and it is possible to prevent such defects as a rough surface of a coated film upon the formation thereof and such a pattern shape as scum appearing at the bottom portion of the pattern upon development, and to secure excellent transmittance.

(D) Solvent

The positive-type photosensitive resin composition of the present invention may be prepared in the form of a liquid composition in which the above components are mixed with a solvent. The solvent may be, for example, an organic solvent.

The amount of the solvent in the positive-type photosensitive resin composition according to the present invention is not particularly limited. For example, the solvent may be employed such that the solids content is 10 to 70% by weight, preferably 15 to 60% by weight, based on the total weight of the composition.

The term solids content refers to the components that constitute the composition, exclusive of solvents. If the amount of the solvent is within the above range, the coating of the composition can be readily carried out, and the flowability thereof can be maintained at a proper level.

The solvent of the present invention is not particularly limited as long as it can dissolve the above-mentioned components and is chemically stable. For example, the solvent may be alcohols, ethers, glycol ethers, ethylene glycol alkyl ether acetates, diethylene glycol, propylene glycol monoalkyl ethers, propylene glycol alkyl ether acetates, propylene glycol alkyl ether propionates, aromatic hydrocarbons, ketones, esters, or the like.

Particular examples of the solvent include methanol, ethanol, tetrahydrofuran, dioxane, methyl cellosolve acetate, ethyl cellosolve acetate, ethyl acetoacetate, ethylene glycol monomethyl ether, ethylene glycol monoethyl ether, ethylene glycol dimethyl ether, ethylene glycol diethyl ether, propylene glycol dimethyl ether, propylene glycol diethyl ether, diethylene glycol monomethyl ether, diethylene glycol monoethyl ether, diethylene glycol dimethyl ether, diethylene glycol ethyl methyl ether, propylene glycol monomethyl ether, propylene glycol monoethyl ether, propylene glycol monopropyl ether, dipropylene glycol dimethyl ether, dipropylene glycol diethyl ether, propylene glycol methyl ether acetate, propylene glycol ethyl ether acetate, propylene glycol propyl ether acetate, dipropylene glycol methyl ether acetate, propylene glycol butyl ether acetate, toluene, xylene, methyl ethyl ketone, 4-hydroxy-4-methyl-2-pentanone, cyclopentanone, cyclohexanone, 2-heptanone, γ-butyrolactone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 2-methoxypropionate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, N,N-dimethylformamide, N,N-dimethylacetamide, N-methylpyrrolidone, and the like.

Preferred among the above are ethylene glycol alkyl ether acetates, diethylene glycols, propylene glycol monoalkyl ethers, propylene glycol alkyl ether acetates, ketones and the like. In particular, preferred are diethylene glycol dimethyl ether, diethylene glycol ethyl methyl ether, dipropylene glycol dimethyl ether, dipropylene glycol diethyl ether, propylene glycol monomethyl ether, propylene glycol monoethyl ether, propylene glycol methyl ether acetate, methyl 2-methoxypropionate, γ-butyrolactone, 4-hydroxy-4-methyl-2-pentanone, and the like.

The solvents exemplified above may be used alone or in combination of two or more thereof.

(E) Epoxy Compound

In the positive-type photosensitive resin composition according to the present invention, an epoxy compound may additionally be employed together with the siloxane copolymer (B) so as to increase the internal density of a siloxane binder (i.e., siloxane copolymer), to thereby improve the chemical resistance of a cured film to be prepared therefrom.

The epoxy compound may be a homo-oligomer or a hetero-oligomer of an unsaturated monomer containing at least one epoxy group.

Examples of the unsaturated monomer containing at least one epoxy group may include glycidyl (meth)acrylate, 4-hydroxybutylacrylate glycidyl ether, 3,4-epoxybutyl (meth)acrylate, 4,5-epoxypentyl (meth)acrylate, 5,6-epoxyhexyl (meth)acrylate, 6,7-epoxyheptyl (meth)acrylate, 2,3-epoxycyclopentyl (meth)acrylate, 3,4-epoxycyclohexyl (meth)acrylate, α-ethyl glycidyl acrylate, α-n-propyl glycidyl acrylate, α-n-butyl glycidyl acrylate, N-(4-(2,3-epoxypropoxy)-3,5-dimethylbenzyl)acrylamide, N-(4-(2,3-epoxypropoxy)-3,5-dimethylphenylpropyl)acrylamide, allyl glycidyl ether, 2-methylallyl glycidyl ether, o-vinylbenzyl glycidyl ether, m-vinylbenzyl glycidyl ether, p-vinylbenzyl glycidyl ether, and a mixture thereof. Preferably, glycidyl methacrylate may be used.

The epoxy compound may be synthesized by any methods well known in the art.

An example of the commercially available epoxy compound may be GHP03 (glycidyl methacrylate homopolymer, Miwon Commercial Co., Ltd.).

The epoxy compound (E) may further comprise the following structural unit.

Particular examples thereof may include any structural unit derived from styrene; a styrene having an alkyl substituent such as methylstyrene, dimethylstyrene, trimethylstyrene, ethylstyrene, diethylstyrene, triethylstyrene, propylstyrene, butylstyrene, hexylstyrene, heptylstyrene, and octylstyrene; a styrene having a halogen such as fluorostyrene, chlorostyrene, bromostyrene, and iodostyrene; a styrene having an alkoxy substituent such as methoxystyrene, ethoxystyrene, and propoxystyrene; an acetylstyrene such as p-hydroxy-α-methylstyrene; an ethylenically unsaturated compound having an aromatic ring such as divinylbenzene, vinylphenol, o-vinylbenzyl methyl ether, m-vinylbenzyl methyl ether, and p-vinylbenzyl methyl ether; an unsaturated carboxylic acid ester such as methyl (meth)acrylate, ethyl (meth)acrylate, butyl (meth)acrylate, dimethylaminoethyl (meth)acrylate, isobutyl (meth)acrylate, t-butyl (meth)acrylate, cyclohexyl (meth)acrylate, ethylhexyl (meth)acrylate, tetrahydrofurfuryl (meth)acrylate, hydroxyethyl (meth)acrylate, 2-hydroxypropyl (meth)acrylate, 2-hydroxy-3-chloropropyl (meth)acrylate, 4-hydroxybutyl (meth)acrylate, glycerol (meth)acrylate, methyl α-hydroxymethylacrylate, ethyl α-hydroxymethylacrylate, propyl α-hydroxymethylacrylate, butyl α-hydroxymethylacrylate, 2-methoxyethyl (meth)acrylate, 3-methoxybutyl (meth)acrylate, ethoxy diethylene glycol (meth)acrylate, methoxy triethylene glycol (meth)acrylate, methoxy tripropylene glycol (meth)acrylate, poly(ethylene glycol) methyl ether (meth)acrylate, phenyl (meth)acrylate, benzyl (meth)acrylate, 2-phenoxyethyl (meth)acrylate, phenoxy diethylene glycol (meth)acrylate, p-nonylphenoxy polyethylene glycol (meth)acrylate, p-nonylphenoxy polypropylene glycol (meth)acrylate, tetrafluoropropyl (meth)acrylate, 1,1,1,3,3,3-hexafluoroisopropyl (meth)acrylate, octafluoropentyl (meth)acrylate, heptadecafluorodecyl (meth)acrylate, tribromophenyl (meth)acrylate, isobornyl (meth)acrylate, dicyclopentanyl (meth)acrylate, dicyclopentenyl (meth)acrylate, dicyclopentanyloxyethyl (meth)acrylate, and dicyclopentenyloxyethyl (meth)acrylate; a tertiary amine having an N-vinyl group such as N-vinyl pyrrolidone, N-vinyl carbazole, and N-vinyl morpholine; an unsaturated ether such as vinyl methyl ether and vinyl ethyl ether; an unsaturated imide such as N-phenylmaleimide, N-(4-chlorophenyl)maleimide, N-(4-hydroxyphenyl)maleimide, and N-cyclohexylmaleimide. The structural unit derived from the compounds exemplified above may be contained in the epoxy compound (E) alone or in combination of two or more thereof.

The styrene-based compounds among the above compounds may be preferable in consideration of polymerizability.

In particular, it is more preferable in terms of the chemical resistance that the epoxy compound (E) does not contain a carboxyl group by way of not using a structural unit derived from a monomer containing a carboxyl group among the above.

The structural unit may be employed in an amount of 0 to 70% by mole, preferably 10 to 60% by mole, based on the total number of moles of the structural units constituting the epoxy compound (E). Within the above content range, it may be more advantageous in terms of the film strength.

The weight average molecular weight of the epoxy compound (E) may preferably be 100 to 30,000 Da. The weight average molecular weight thereof may more preferably be 1,000 to 15,000 Da. If the weight average molecular weight of the epoxy compound is at least 100 Da, the hardness of a cured film may be more favorable. If it is 30,000 Da or less, a cured film may have a uniform thickness, which is suitable for planarizing any steps thereon.

In the positive-type photosensitive resin composition of the present invention, the epoxy compound (E) may be employed in an amount of 0 to 40 parts by weight, preferably 5 to 25 parts by weight, based on 100 parts by weight of the acrylic copolymer (A) on the basis of the solids content. Within the above content range, the chemical resistance and adhesiveness of the photosensitive resin composition may be more favorable.

(F) Silane Compound

The positive-type photosensitive resin composition of the present invention may comprise at least one silane compound represented by the following Formula 3, particularly, silane monomers of T type and/or Q type, to thereby enhance the chemical resistance during the treatment in the post-processing by reducing highly reactive silanol groups (Si-OH) in the siloxane copolymer, in association with the epoxy compound, for instance epoxy oligomers.

(R⁵)ₙSi(OR⁶)₄₋ₙ [Formula 3]

In the above Formula 3, n is an integer of 0 to 3, R⁵ is each independently C₁₋₁₂ alkyl, C₂₋₁₀ alkenyl, C₆₋₁₅ aryl, 3- to 12-membered heteroalkyl, 4- to 10-membered heteroalkenyl, or 6- to 15-membered heteroaryl, and R⁶ is each independently hydrogen, C₁₋₆ alkyl, C₂₋₆ acyl, or C₆₋₁₅ aryl, wherein the heteroalkyl, the heteroalkenyl, and the heteroaryl groups each independently have at least one heteroatom selected from the group consisting of O, N, and S.

Examples of the structural unit wherein R⁵ has a heteroatom include an ether, an ester, and a sulfide.

According to the present invention, the compound may be a tetrafunctional silane compound where n is 0, a trifunctional silane compound where n is 1, a difunctional silane compound where n is 2, or a monofunctional silane compound where n is 3.

Particular examples of the silane compound may include, e.g., as the tetrafunctional silane compound, tetraacetoxysilane, tetramethoxysilane, tetraethoxysilane, tetrabutoxysilane, tetraphenoxysilane, tetrabenzyloxysilane, and tetrapropoxysilane; as the trifunctional silane compound, methyltrimethoxysilane, methyltriethoxysilane, methyltriisopropoxysilane, methyltributoxysilane, ethyltrimethoxysilane, ethyltriethoxysilane, ethyltriisopropoxysilane, ethyltributoxysilane, butyltrimethoxysilane, phenyltrimethoxysilane, phenyltriethoxysilane, d³-methyltrimethoxysilane, n-propyltrimethoxysilane, n-propyltriethoxysilane, n-butyltriethoxysilane, n-hexyltrimethoxysilane, n-hexyltriethoxysilane, decyltrimethoxysilane, vinyltrimethoxysilane, vinyltriethoxysilane, 3-methacryloxypropyltrimethoxysilane, 3-methacryloxypropyltriethoxysilane, 3-acryloxypropyltrimethoxysilane, 3-acryloxypropyltriethoxysilane, p-hydroxyphenyltrimethoxysilane, 1-(p-hydroxyphenyl)ethyltrimethoxysilane, 2-(p-hydroxyphenyl)ethyltrimethoxysilane, 4-hydroxy-5-(p-hydroxyphenylcarbonyloxy)pentyltrimethoxysilane, 3-aminopropyltrimethoxysilane, 3-aminopropyltriethoxysilane, 3-glycidoxypropyltrimethoxysilane, 3-glycidoxypropyltriethoxysilane, 2-(3,4-epoxycyclohexyl)ethyltrimethoxysilane, 2-(3,4-epoxycyclohexyl)ethyltriethoxysilane, [(3-ethyl-3-oxetanyl)methoxy]propyltrimethoxysilane, [(3-ethyl-3-oxetanyl)methoxy]propyltriethoxysilane, 3-mercaptopropyltrimethoxysilane, and 3-trimethoxysilylpropylsuccinic acid; as the difunctional silane compound, dimethyldiacetoxysilane, dimethyldimethoxysilane, diphenyldimethoxysilane, diphenyldiethoxysilane, diphenyldiphenoxysilane, dibutyldimethoxysilane, dimethyldiethoxysilane, (3-glycidoxypropyl)methyldimethoxysilane, (3-glycidoxypropyl)methyldiethoxysilane, 3-(2-aminoethylamino)propyldimethoxymethylsilane, 3-aminopropyldiethoxymethylsilane, 3-mercaptopropyldimethoxymethylsilane, cyclohexyldimethoxymethylsilane, diethoxymethylvinylsilane, dimethoxymethylvinylsilane, and dimethoxydi-p-tolylsilane; and as the monofunctional silane compound, trimethylsilane, tributylsilane, trimethylmethoxysilane, tributylethoxysilane, (3-glycidoxypropyl)dimethylmethoxysilane, and (3-glycidoxypropyl)dimethylethoxysilane.

Preferred among the tetrafunctional silane compounds are tetramethoxysilane, tetraethoxysilane, and tetrabutoxysilane; preferred among the trifunctional silane compounds are methyltrimethoxysilane, methyltriethoxysilane, methyltriisopropoxysilane, methyltributoxysilane, phenyltrimethoxysilane, ethyltrimethoxysilane, ethyltriethoxysilane, ethyltriisopropoxysilane, ethyltributoxysilane, butyltrimethoxysilane, 3-glycidoxypropyltrimethoxysilane, 3-glycidoxypropyltriethoxysilane, 2-(3,4-epoxycyclohexyl)ethyltrimethoxysilane, and 2-(3,4-epoxycyclohexyl)ethyltriethoxysilane; preferred among the difunctional silane compounds are dimethyldimethoxysilane, diphenyldimethoxysilane, diphenyldiethoxysilane, diphenyldiphenoxysilane, dibutyldimethoxysilane, and dimethyldiethoxysilane.

These silane compounds may be used alone or in combination of two or more thereof.

The silane compound (F) may be employed in an amount of 0 to 20 parts by weight, preferably 4 to 12 parts by weight, based on 100 parts by weight of the acrylic copolymer (A) on the basis of the solids content. Within the above content range, the chemical resistance of a cured film to be formed may be further enhanced.

(G) Surfactant

The positive-type photosensitive resin composition of the present invention may further comprise a surfactant to enhance its coatability, if desired.

The kind of the surfactant is not limited. Examples thereof may include fluorine-based surfactants, silicon-based surfactants, non-ionic surfactants, and the like.

Specific examples of the surfactant (G) may include fluorine- and silicon-based surfactants such as FZ-2122 supplied by Dow Corning Toray Co., Ltd., BM-1000 and BM-1100 supplied by BM CHEMIE Co., Ltd., Megapack F-142 D, F-172, F-173, and F-183 supplied by Dai Nippon Ink Chemical Kogyo Co., Ltd., Florad FC-135, FC-170 C, FC-430, and FC-431 supplied by Sumitomo 3M Ltd., Sufron S-112, S-113, S-131, S-141, S-145, S-382, SC-101, SC-102, SC-103, SC-104, SC-105, and SC-106 supplied by Asahi Glass Co., Ltd., Eftop EF301, EF303, and EF352 supplied by Shinakida Kasei Co., Ltd., SH-28 PA, SH-190, SH-193, SZ-6032, SF-8428, DC-57, and DC-190 supplied by Toray Silicon Co., Ltd.; non-ionic surfactants such as polyoxyethylene alkyl ethers including polyoxyethylene lauryl ether, polyoxyethylene stearyl ether, polyoxyethylene oleyl ether, and the like; polyoxyethylene aryl ethers including polyoxyethylene octylphenyl ether, polyoxyethylene nonylphenyl ether, and the like; and polyoxyethylene dialkyl esters including polyoxyethylene dilaurate, polyoxyethylene distearate, and the like; and organosiloxane polymer KP341 (manufactured by Shin-Etsu Chemical Co., Ltd.), (meth)acrylate-based copolymer Polyflow Nos. 57 and 95 (manufactured by Kyoei Yuji Chemical Co., Ltd.), and the like. They may be used alone or in combination of two or more thereof.

The surfactant (G) may be employed in an amount of 0.001 to 5 parts by weight, preferably 0.05 to 2 parts by weight, based on the total weight of the photosensitive resin composition. Within the above range, the coating of the composition is smoothly carried out.

(H) Adhesion Supplement

The photosensitive resin composition of the present invention may further comprise an adhesion supplement to enhance the adhesiveness to a substrate.

The adhesion supplement may have at least one reactive group selected from the group consisting of a carboxyl group, a (meth)acryloyl group, an isocyanate group, an amino group, a mercapto group, a vinyl group, and an epoxy group.

The kind of the adhesion supplement is not particularly limited. It may be at least one selected from the group consisting of trimethoxysilyl benzoic acid, γ-methacryloxypropyltrimethoxysilane, vinyltriacetoxysilane, vinyltrimethoxysilane, γ-isocyanatopropyltriethoxysilane, γ-glycidoxypropyltrimethoxysilane, γ-glycidoxypropyltriethoxysilane, N-phenylaminopropyltrimethoxysilane, and β-(3,4-epoxycyclohexyl)ethyltrimethoxysilane. Preferred is γ-glycidoxypropyltrimethoxysilane, γ-glycidoxypropyltriethoxysilane, or N-phenylaminopropyltrimethoxysilane, which is capable of enhancing the film retention rate and is excellent in the adhesiveness to a substrate.

The adhesion supplement (H) may be employed in an amount of 0 to 5 parts by weight, preferably 0.001 to 2 parts by weight, based on the total weight of the photosensitive resin composition. Within the above range, the adhesiveness to a substrate may be further enhanced.

In addition, the photosensitive resin composition of the present invention may further comprise other additives as long as the physical properties of the photosensitive resin composition are not adversely affected.

The photosensitive resin composition according to the present invention may be used as a positive-type photosensitive resin composition.

In particular, the positive-type photosensitive resin composition of the present invention comprises an acrylic copolymer, which has a functional group that can freely rotate in the polymer, whereby the sensitivity can be further enhanced.

The present invention provides a cured film formed from the photosensitive resin composition.

The cured film may be formed by a method known in the art, for example, a method in which the photosensitive resin composition is coated on a substrate and then cured.

More specifically, in the curing step, the photosensitive resin composition coated on a substrate may be subjected to pre-bake at a temperature of, for example, 60 to 130° C. to remove solvents; then exposed to light using a photomask having a desired pattern; and subjected to development using a developer, for example, a tetramethylammonium hydroxide (TMAH) solution to form a pattern on the coating layer. Thereafter, the patterned coating layer, if necessary, is subjected to post-bake, for example, at a temperature of 150 to 300° C. for 10 minutes to 5 hours to prepare a desired cured film. The exposure to light may be carried out at an exposure rate of 10 to 200 mJ/cm² based on a wavelength of 365 nm in a wavelength band of 200 to 500 nm. According to the process of the present invention, it is possible to easily form a desired pattern from the viewpoint of the process.

The coating of the photosensitive resin composition onto a substrate may be carried out by a spin coating method, a slit coating method, a roll coating method, a screen printing method, an applicator method, or the like, in a desired thickness of, e.g., 2 to 25 μm. In addition, as a light source used for the exposure (irradiation), a low-pressure mercury lamp, a high-pressure mercury lamp, an extra high-pressure mercury lamp, a metal halide lamp, an argon gas laser, or the like may be used. X-ray, electronic ray, or the like may also be used, if desired.

The photosensitive resin composition of the present invention is capable of forming a cured film that is excellent in terms of the heat resistance, transparency, dielectric constant, solvent resistance, acid resistance, and alkali resistance. Therefore, the cured film of the present invention thus formed has excellent light transmittance devoid of surface roughness when it is subjected to heat treatment or is immersed in, or comes into contact with a solvent, an acid, a base, or the like. Thus, the cured film can be effectively used as a planarization film for a thin-film transistor (TFT) substrate of a liquid crystal display or an organic EL display; a partition of an organic EL display; an interlayer dielectric of a semiconductor device; a core or cladding material of an optical waveguide, or the like. Further, the present invention provides an electronic part that comprises the cured film as a protective film.

### MODE FOR THE INVENTION

Hereinafter, the present invention will be described in more detail with reference to the following examples. However, these examples are provided to illustrate the present invention, and the scope of the present invention is not limited thereto only.

In the following synthesis examples, the weight average molecular weight is determined by gel permeation chromatography (GPC, eluent: tetrahydrofuran) referenced to a polystyrene standard.

### Synthesis Example 1: Synthesis of an Acrylic Copolymer (A-1)

A flask equipped with a cooling tube and a stirrer was charged with 200 parts by weight of propylene glycol monomethyl ether acetate (PGMEA) as a solvent, and the temperature of the solvent was raised to 70□ while the solvent was stirred slowly. Subsequently, added thereto were 20.3 parts by weight of styrene (Sty), 29.3 parts by weight of methyl methacrylate (MMA), 20.8 parts by weight of glycidyl methacrylate (GMA), 17.6 parts by weight of methacrylic acid (MAA), and 12.0 parts by weight of methyl acrylate (MA). Next, 3 parts by weight of 2,2′-azobis(2,4-dimethylvaleronitrile) as a radical polymerization initiator was added thereto dropwise over 5 hours to carry out a polymerization reaction. The weight average molecular weight of the copolymer thus obtained (solids content: 32% by weight) was 9,000 to 11,000 Da.

### Synthesis Examples 2 to 5: Synthesis of Acrylic Copolymers (A-2 to A-5)

Acrylic copolymers (A-2 to A-5) were each obtained in the same manner as in Example 1 except that the kinds and contents of the respective components were changed as shown in Table 1 below.

TABLE 1

| | | | | | | | Weight |
|---|---|---|---|---|---|---|---|
| | | | | | | | average |
| | | | | | | | molecular |
| Acrylic | | | | | | Solids | weight |
| copolymer | Sty | MMA | GMA | MAA | MA | content | (Da) |
| A-1 | 20.3 | 29.3 | 20.8 | 17.6 | 12.0 | 32 | 9,000 to |
| | | | | | | | 11,000 |
| A-2 | 20.2 | 32.6 | 20.7 | 17.6 | 9.0 | 32 | 9,000 to |
| | | | | | | | 11,000 |
| A-3 | 20.1 | 35.8 | 20.6 | 17.5 | 6.0 | 32 | 9,000 to |
| | | | | | | | 11,000 |
| A-4 | 20.1 | 39.0 | 20.5 | 17.4 | 3.0 | 32 | 9,000 to |
| | | | | | | | 11,000 |
| A-5 | 20.0 | 42.2 | 20.4 | 17.3 | 0.0 | 32 | 9,000 to |
| | | | | | | | 11,000 |

### Synthesis Example 6: Synthesis of a Siloxane Polymer (B)

A reactor equipped with a reflux condenser was charged with 20% parts by weight of phenyltrimethoxysilane, 30 parts by weight of methyltrimethoxysilane, 20 parts by weight of tetraethoxysilane, and 15% by weight of purified water, followed by an addition of 15% by weight of propylene glycol monomethyl acetate (PGMA, Chemtronics), which was stirred with refluxing for 6 hours in the presence of 0.1% by weight of an oxalic acid catalyst. Then, the mixture was cooled and diluted with PGMEA such that the solids content was 30%, thereby obtaining a siloxane polymer (B). As a result of a GPC analysis, the weight average molecular weight of the polymer was 9,000 to 15,000 Da as referenced to polystyrene.

### Synthesis Example 7: Preparation of an Epoxy Compound (E)

A three-necked flask was equipped with a cooling tube and placed on a stirrer equipped with a thermostat. The flask was charged with 100 parts by weight of a monomer composed of 100% by mole of glycidyl methacrylate, 10 parts by weight of 2,2′-azobis(2-methylbutyronitrile), and 100 parts by weight of propylene glycol monomethyl ether acetate (PGMEA), followed by charging nitrogen thereto. Thereafter, the temperature of the solution was raised to 80□ while it was slowly stirred, and this temperature was maintained for 5 hours. Then, PGMEA was added such that the solids content was 20% by weight, thereby obtaining an epoxy compound having a weight average molecular weight of 3,000 to 6,000 Da.

### EXAMPLES AND COMPARATIVE EXAMPLES: PREPARATION OF PHOTOSENSITIVE RESIN COMPOSITIONS

The photosensitive resin compositions of the following Examples and Comparative Examples were prepared using the compounds prepared in the above Synthesis Examples.

The components used in the following Examples and Comparative Examples are as follows.

TABLE 2

| | | | Solids |
|---|---|---|---|
| | Compound name | | content |
| Component | and/or brand name | Manufacturer | (wt %) |
| Acrylic copolymer | Synthesis Examples | — | 32 |
| (A) | 1 to 5 | | |
| Siloxane copolymer | Synthesis Example | — | 30 |
| (B) | 6 | | |
| 1,2-quinonediazide | TPA-523 | Miwon | 100 |
| (C) | | Commercial | |
| Solvent (D) | Propylene glycol | Chemtronics | Solvent |
| | monomethyl ether | | |
| | acetate (PGMEA) | | |
| Epoxy compound | Synthesis Example | — | 20 |
| (E) | 7 | | |
| Surfactant | Silicone-based | Dow Corning | 100 |
| (G) | leveling surfactant, | Toray | |
| | FZ-2122 | | |

### Example 1: Preparation of a Photosensitive Resin Composition

57.92% by weight of the acrylic copolymer (A-1) of Synthesis Example 1, based on the total weight of a photosensitive resin composition excluding the solvent in a balanced amount, 45.45 parts by weight of the siloxane copolymer (B) of Synthesis Example 6 based on 100 parts by weight of the acrylic copolymer (on the basis of the solids content), 6.06 parts by weight of the epoxy compound (E) of Synthesis Example 7 based on 100 parts by weight of the acrylic copolymer (on the basis of the solids content), 20.72 parts by weight of the 1,2-quinonediazide compound (C) based on 100 parts by weight of the acrylic copolymer (on the basis of the solids content), and 0.24 parts by weight of the surfactant (G) based on 100 parts by weight of the acrylic copolymer (on the basis of the solids content) were homogeneously mixed and dissolved for 3 hours in PGMEA as the solvent (D) such that the solids content was 22%. It was filtered through a membrane filter having a pore size of 0.2 μm to obtain a composition solution having a solids content of 22% by weight.

### Examples 2 to 4 and Comparative Example 1

Photosensitive resin composition solutions were each prepared in the same manner as in Example 1, except that the kinds and/or contents of the respective components were changed as shown in Table 3 below.

TABLE 3

| | Acrylic | | Siloxane | 1,2- | Epoxy | Surfac- |
|---|---|---|---|---|---|---|
| | copolymer | | copolymer | quinonediazide | compound | tant |
| | (A) | | (B) | (C) | (E) | (G) |
| Ex. 1 | A-1 | 57.92 | 45.45 | 20.72 | 6.06 | 0.24 |
| Ex. 2 | A-2 | 57.92 | 45.45 | 20.72 | 6.06 | 0.24 |
| Ex. 3 | A-3 | 57.92 | 45.45 | 20.72 | 6.06 | 0.24 |
| Ex. 4 | A-4 | 57.92 | 45.45 | 20.72 | 6.06 | 0.24 |
| C. Ex. 1 | A-5 | 57.92 | 45.45 | 20.72 | 6.06 | 0.24 |

### Test Example 1: Evaluation of Sensitivity

The compositions prepared in the Examples and the Comparative Examples were each coated onto a glass substrate by spin coating. The coated substrate was then pre-baked on a hot plate kept at 105 □ for 105 seconds to remove the solvent, thereby forming a dry film. A mask having a pattern of square holes in a size ranging from 1 μm to 30 μm was placed on the dried film. The film was then exposed to light using an aligner (model name: MA6) that emits light having a wavelength of 200 nm to 450 nm.

In such event, the gap between the mask and the substrate was 25 μm based on the light exposure, and the exposure was performed for a certain time period at an exposure rate of 0 to 200 mJ/cm² based on a wavelength of 365 nm (i.e., bleaching step). It was then developed for 80 seconds with a developer, which was an aqueous solution of 2.38% by weight of tetramethylammonium hydroxide, through puddle nozzles at 23□. The developed film was then exposed to light at an exposure rate of 40 mJ/cm² and 80 mJ/cm² based on a wavelength of 365 nm for a certain time period using an aligner (model name: MA6) that emits light having a wavelength of 200 nm to 450 nm (i.e., bleaching step). The exposed film was heated in a convection oven at 2300 for 30 minutes to prepare a cured film having a thickness of 3.5 μm. For the hole pattern formed per a size of the mask of 10 μm in the above procedure, the amount of exposure energy for attaining a critical dimension (CD, unit: μm) of 10 μm was measured. The lower the value (mJ/cm²), the better the sensitivity.

### Test Example 2: Evaluation of the Size of CD in Patterned Hall Pattern

The compositions prepared in the Examples and the Comparative Examples were each coated onto a glass substrate by spin coating. The coated substrate was then pre-baked on a hot plate kept at 105 □ for 105 seconds to remove the solvent, thereby forming a dry film. The dried film was exposed, through a mask having a pattern of square holes in a size ranging from 1 μm to 30 μm, to light at an exposure rate of 0 to 200 mJ/cm² based on a wavelength of 365 nm for a certain time period using an aligner (model name: MA6) that emits light having a wavelength of 200 nm to 450 nm. In such event, the gap between the mask and the substrate was 25 μm based on the light exposure (i.e., bleaching step). It was then developed for 80 seconds with a developer, which was an aqueous solution of 2.38% by weight of tetramethylammonium hydroxide, through puddle nozzles at 23□. The developed film was then exposed to light at an exposure rate of 40 mJ/cm² and 80 mJ/cm² based on a wavelength of 365 nm for a certain time period using an aligner (model name: MA6) that emits light having a wavelength of 200 nm to 450 nm (i.e., bleaching step). The exposed film was heated in a convection oven at 230 □ for 30 minutes to prepare a cured film having a thickness of 3.5 μm. For the hole pattern formed per a size of the mask of 10 μm in the above procedure, the size of CD was measured. The larger the hole size of 10 μm, the faster the sensitivity.

TABLE 4

| | |
|---|---|
| Sensitivity | 10 μm CD size |

| | (mJ/cm²) | 40 mJ/cm² | 80 mJ/cm² |
|---|---|---|---|
| Ex. 1 | 20 | 14.9 | 17.3 |
| Ex. 2 | 25 | 14.2 | 16.2 |
| Ex. 3 | 31 | 13.0 | 15.3 |
| Ex. 4 | 36 | 11.9 | 14.1 |
| C. Ex. 1 | 44 | 11.0 | 13.5 |

As shown in Table 4, the compositions of the Examples, falling within the scope of the present invention, were fast and excellent in sensitivity, whereas the compositions of the Comparative Example, falling outside the scope of the present invention, was poor in sensitivity

1. A positive-type photosensitive resin composition, which comprises:
(A) an acrylic copolymer;
(B) a siloxane copolymer; and
(C) a 1,2-quinonediazide compound,
wherein the acrylic copolymer (A) comprises a structural unit (a-1) represented by the following Formula 1: 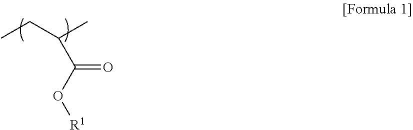
in the above Formula 1, R¹ is C₁₋₄ alkyl.

2. The positive-type photosensitive resin composition of claim 1, wherein the acrylic copolymer (A) further comprises a structural unit (a-2) represented by the following Formula 1-1: 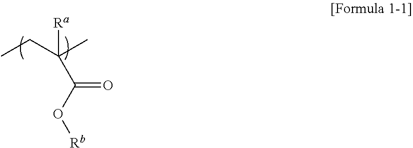
in the above Formula 1-1, R^{a} and R^{b} are each independently C₁₋₄ alkyl.

3. The positive-type photosensitive resin composition of claim 2, wherein the structural unit (a-1) and the structural unit (a-2) have a content ratio of 1:99 to 80:20.

4. The positive-type photosensitive resin composition of claim 1, wherein the acrylic copolymer (A) comprises a structural unit (a-3) derived from an ethylenically unsaturated carboxylic acid, an ethylenically unsaturated carboxylic anhydride, or a combination thereof in an amount of 5 to 30% by weight based on the total weight of the acrylic copolymer (A).

5. The positive-type photosensitive resin composition of claim 1, wherein the siloxane copolymer (B) comprises a structural unit derived from a silane compound represented by the following Formula 2:
(R³)ₙSi(OR⁴)₄₋ₙ [Formula 2]
in the above Formula 2,
n is an integer of 0 to 3;
R³ is each independently C₁₋₁₂ alkyl, C₂₋₁₀ alkenyl, C₆₋₁₅ aryl, 3- to 12-membered heteroalkyl, 4- to 10-membered heteroalkenyl, or 6- to 15-membered heteroaryl, and
R⁴ is each independently hydrogen, C₁₋₆ alkyl, C₂₋₆ acyl, or C₆₋₁₅ aryl,
wherein the heteroalkyl, the heteroalkenyl, and the heteroaryl groups each independently have at least one heteroatom selected from the group consisting of O, N, and S.

6. The positive-type photosensitive resin composition of claim 1, wherein the siloxane copolymer (B) is employed in an amount of 1 to 400 parts by weight based on 100 parts by weight of the acrylic copolymer (A) on the basis of the solids content.

7. The positive-type photosensitive resin composition of claim 1, wherein the 1,2-quinonediazide-based compound (C) is employed in an amount of 2 to 30 parts by weight based on 100 parts by weight of the acrylic copolymer (A) on the basis of the solids content.

8. The positive-type photosensitive resin composition of claim 1, which further comprises an epoxy compound.

9. A cured film prepared from the positive-type photosensitive resin composition of claim 1.
